(19) United States
(12) Patent Application Publication
(10) Pub. No.: US 2024/0283950 A1
(43) Pub. Date: Aug. 22, 2024

(54) METHOD FOR MANAGING AN IMAGE IN AN AUTOMOTIVE LIGHTING DEVICE AND AN AUTOMOTIVE LIGHTING DEVICE

(71) Applicant: VALEO VISION, Bobigny (FR)

(72) Inventor: Yasser ALMEHIO, Bobigny (FR)

(73) Assignee: VALEO VISION, Bobigny (FR)

(21) Appl. No.: 18/568,990

(22) PCT Filed: Jun. 22, 2022
(86) PCT No.: PCT/EP2022/067064

§ 371 Date: Dec. 11, 2023

(30) Foreign Application Priority Data
Jun. 24, 2021 (FR) FR2106746

(51) Int. Cl. H04N 19/182; F21S 41/141; F21S 41/50; F21Y 115/10; H04N 19/91

(52) U.S. Cl. CPC H04N 19/182; F21S 41/141; F21S 41/50; H04N 19/91; F21Y 2115/10

(57) ABSTRACT

A method for managing an image in an automotive lighting device. The method includes providing a first image pattern including a plurality of pixels, selecting a relevant portion of the value of each pixel and preparing compressed data related to the relevant values, together with data related to the position of the pixel with a value equal to zero.

### TECHNICAL FIELD

This invention is related to the field of automotive lighting devices, and more particularly, to the management of the electronic data derived from the control of the lighting sources.

### BACKGROUND OF THE INVENTION

Current lighting devices comprises an increasing number of light sources which have to be controlled, to provide adaptive lighting functionalities.

This number of light sources involves a big amount of data, which has to be managed by the PCM. The CAN protocol is often used, in some of their variants (CAN-FD is one of the most used ones) to transfer data between the PCM and the light module. However, some car manufacturers decide to limit the bandwidth of the CAN protocol, and this affects the management operations, which usually requires about 5 Mbps.

In fact, when the system deals with images in movement, the problem of saving data size is crucial, since it affects to the speed in the data transmission and therefore to the speed in images projection.

Further, there are some light functionalities, such as welcome light and goodbye light, which provide animations which are not linear, so their data cannot be grouped or associated to obtain a better compression rate.

A solution for this problem is sought.

### BRIEF SUMMARY OF THE INVENTION

The invention provides a solution for these problems by means of a method for managing image data according to claim 1 and an automotive lighting device according to claim 8. Preferred embodiments of the invention are defined in dependent claims.

Unless otherwise defined, all terms (including technical and scientific terms) used herein are to be interpreted as is customary in the art. It will be further understood that terms in common usage should also be interpreted as is customary in the relevant art and not in an idealized or overly formal sense unless expressly so defined herein.

In this text, the term “comprises” and its derivations (such as “comprising”, etc.) should not be understood in an excluding sense, that is, these terms should not be interpreted as excluding the possibility that what is described and defined may include further elements, steps, etc.

In a first inventive aspect, the invention provides a method for managing image data in an automotive lighting device, the method comprising the steps of:

providing a first image pattern comprising a plurality of pixels, wherein each pixel is characterized by a value related to the luminous intensity of the pixel, wherein the value of a plurality of pixels is zero;

select a relevant portion of the value of each pixel, thus obtaining relevant values; and

prepare compressed data related to the relevant values, together with data related to the position of the pixel with a value equal to zero.

In this method, which is especially advantageous in the event of a multitude of zero-light zones scattered along the light pattern. The values of the zero-light pixels are not altered, while the values of the rest of the pixels are approximated according to their relevant value.

This means that the base structure of the original light pattern remains the same, and minor changes are registered only in the particular luminous intensity values.

In some particular embodiments, the light pixels of the image pattern are greyscale pixels, and more particularly, the luminous intensity of each pixel is characterized by a number according to a scale from 0 to 255, so that each value related to the luminous intensity may be expressed with 8 bits.

This system of greyscale pixels is adopted by the vast majority of the automotive lighting device manufacturers, so the method may be applied to all of them.

In some particular embodiments, the relevant portion of each value are the first 4 bits of the corresponding value.

For each luminous intensity value, expressed in 8 bits, only the first 4 bits, which are the most significant ones, are considered. This means that, for each value, the relevant value is the multiple of 16 which is closer to the corresponding value.

In some particular embodiments, the relevant values are arranged in a unidimensional array, and the compressed data comprises:

a first number of consecutive zeros from the start of the unidimensional array until arriving at a data segment

key data referred to a data segment with non-zero values; and

successively the number of consecutives zeros until the next data segment and the key data referred to the next data segment.

This means that the matrix is firstly transformed into a unidimensional array, i.e., a row. Starting from the first pixel of the row, the number of consecutive zeros until the first non-zero value is stored. Then, some key data referred to the values of a data segment are stored. The data segment is a portion of the pixels row which comprises non-zero values. The key data is the way these values of the data segment are stored. In some cases, the key data is identically the same values of the data segment, but in other cases, the key data stores values which do not identically correspond with the values of the data segment, but only “represent” these values. Once the values of the data segment are stored as key data, the number of the consecutive zeros after this data segment is stored again. By this algorithm, all the values of each row are covered until arriving at the last one. The size and structure of the data segments is chosen depending on the algorithm which best suits the particular light pattern.

In some particular embodiments, all the data segments comprise the same number of pixels.

This is one option for defining the data segment. Instead of covering only the non-zero values, a fixed length of the segment is considered, so that the segment covers all the non-zero values and, occasionally, some zero values as well.

In some particular embodiments, the key data is obtained by applying a key on the values of the data segment. Since the first value of the data segment is a non-zero value, placing one or more zeros as the first values of the key data is advantageously used to reduce data size in special occasions.

In some particular embodiments, a first value of the key involves that all the values of the segment are the same.

If the key data starts with one zero, it means that all the values of the data segment are the same. For example: a key data of (0, 6) means (6, 6, 6, 6, 6, 6, 6, 6).

In some particular embodiments, a second value of the key involves that a first portion of the segment have pixels which have the same first value and a second portion of the segments have pixels which have the same second value.

If the key data starts with two zeros, it means that this data segment is divided into two portions. The first four pixels have one value and the second four pixels have another value. For example: (0, 0, 5, 2) means (5, 5, 5, 5, 2, 2, 2, 2).

In some particular embodiments, the method further comprises the steps of:

sending the compressed data to a light module of the automotive lighting device; and

decompressing the compressed data by the light module.

In a second inventive aspect, the invention provides an automotive lighting device comprising

a light module comprising a plurality of light sources; and

a control unit to carry out the steps of a method according to the first inventive aspect.

In some particular embodiments, the light module further comprises a processor unit, the processor unit being configured to decompress the compressed data.

With a decompression stage in the proper light module, the bandwidth is narrowed until the module itself.

In some particular embodiments, the light sources are solid-state light sources, such as LEDs.

The term “solid state” refers to light emitted by solid-state electroluminescence, which uses semiconductors to convert electricity into light. Compared to incandescent lighting, solid state lighting creates visible light with reduced heat generation and less energy dissipation. The typically small mass of a solid-state electronic lighting device provides for greater resistance to shock and vibration compared to brittle glass tubes/bulbs and long, thin filament wires. They also eliminate filament evaporation, potentially increasing the life span of the illumination device. Some examples of these types of lighting comprise semiconductor light-emitting diodes (LEDs), organic light-emitting diodes (OLED), or polymer light-emitting diodes (PLED) as sources of illumination rather than electrical filaments, plasma or gas.

### BRIEF DESCRIPTION OF THE DRAWINGS

To complete the description and in order to provide for a better understanding of the invention, a set of drawings is provided. Said drawings form an integral part of the description and illustrate an embodiment of the invention, which should not be interpreted as restricting the scope of the invention, but just as an example of how the invention can be carried out. The drawings comprise the following figures:

FIG. 1 shows an automotive lighting device according to the invention.

FIG. 2 shows a first image of the photometry of a welcome light functionality which is to be projected by an automotive lighting device according to the invention.

FIG. 3 shows a simplified version of such a pixel matrix, called image pattern.

FIG. 4 shows how this matrix is flattened into one single row by placing the values of a row after the previous row.

FIG. 5 shows a next step in a method according to the invention.

FIG. 6 shows the relevant values converted again to the decimal system.

FIG. 7a, FIG. 7B, and FIG. 7c show different examples of how to create the compressed

data using a particular key.

### DETAILED DESCRIPTION OF THE INVENTION

In these figures, the following reference numbers have been used:
1 First image pattern
4 Light module
5 LEDs
6 Control unit
7 Processor unit
10 Automotive lighting device
11 Pixel
100 Automotive vehicle

The example embodiments are described in sufficient detail to enable those of ordinary skill in the art to embody and implement the systems and processes herein described. It is important to understand that embodiments can be provided in many alternate forms and should not be construed as limited to the examples set forth herein.

Accordingly, while embodiment can be modified in various ways and take on various alternative forms, specific embodiments thereof are shown in the drawings and described in detail below as examples. There is no intent to limit the invention to the particular forms disclosed. On the contrary, all modifications, equivalents, and alternatives falling within the scope of the appended claims should be included. Elements of the example embodiments are consistently denoted by the same reference numerals throughout the drawings and detailed description where appropriate.

Unless otherwise defined, all terms (including technical and scientific terms) used herein are to be interpreted as is customary in the art. It will be further understood that terms in common usage should also be interpreted as is customary in the relevant art and not in an idealized or overly formal sense unless expressly so defined herein.

In this text, the term “comprises” and its derivations (such as “comprising”, etc.) should not be understood in an excluding sense, that is, these terms should not be interpreted as excluding the possibility that what is described and defined may include further elements, steps, etc.

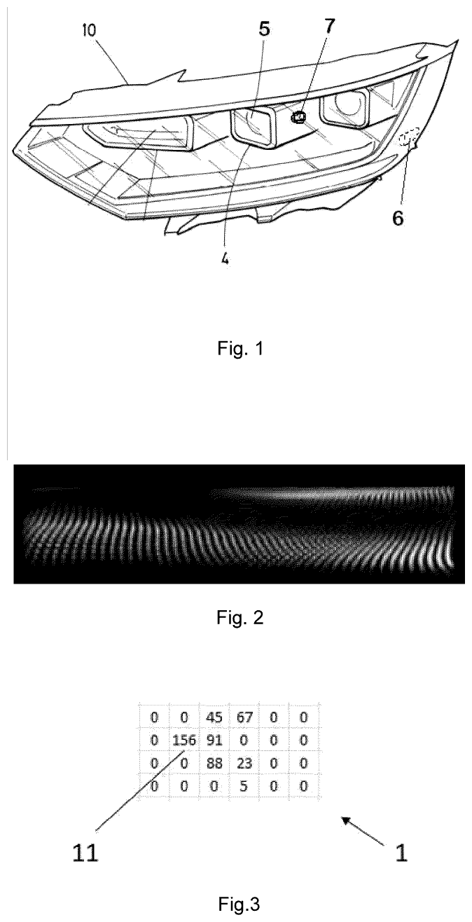

FIG. 1 shows an automotive lighting device according to the invention, this lighting device comprising:

a light module 4 comprising a plurality of LEDs 5;

a control unit 6 to carry out the compression steps, generating the compressed data; and

a processor unit 7, the processor unit 7 being configured to decompress the compressed data, this processor unit being located in the light module 4.

The lighting module 1 has a matrix arrangement of light sources, having a resolution greater than 2000 pixels. However, no restriction is attached to the technology used for producing the projection modules.

A first example of this matrix configuration comprises a monolithic source. This monolithic source comprises a matrix of monolithic electroluminescent elements arranged in several columns by several rows. In a monolithic matrix, the electroluminescent elements can be grown from a common substrate and are electrically connected to be selectively activatable either individually or by a subset of electroluminescent elements. The substrate may be predominantly made of a semiconductor material. The substrate may comprise one or more other materials, for example non-semiconductors (metals and insulators). Thus, each electroluminescent element/group can form a light pixel and can therefore emit light when its/their material is supplied with electricity. The configuration of such a monolithic matrix allows the arrangement of selectively activatable pixels very close to each other, compared to conventional light-emitting diodes intended to be soldered to printed circuit boards. The monolithic matrix may comprise electroluminescent elements whose main dimension of height, measured perpendicularly to the common substrate, is substantially equal to one micrometre.

The monolithic matrix is coupled to the control center so as to control the generation and/or the projection of a pixilated light beam by the matrix arrangement. The control center is thus able to individually control the light emission of each pixel of the matrix arrangement.

Alternatively to what has been presented above, the matrix arrangement 6 may comprise a main light source coupled to a matrix of mirrors. Thus, the pixelated light source is formed by the assembly of at least one main light source formed of at least one light emitting diode emitting light and an array of optoelectronic elements, for example a matrix of micro-mirrors, also known by the acronym DMD, for “Digital Micro-mirror Device”, which directs the light rays from the main light source by reflection to a projection optical element. Where appropriate, an auxiliary optical element can collect the rays of at least one light source to focus and direct them to the surface of the micro-mirror array.

Each micro-mirror can pivot between two fixed positions, a first position in which the light rays are reflected towards the projection optical element, and a second position in which the light rays are reflected in a different direction from the projection optical element. The two fixed positions are oriented in the same manner for all the micro-mirrors and form, with respect to a reference plane supporting the matrix of micro-mirrors, a characteristic angle of the matrix of micro-mirrors defined in its specifications. Such an angle is generally less than 20° and may be usually about 12°. Thus, each micro-mirror reflecting a part of the light beams which are incident on the matrix of micro-mirrors forms an elementary emitter of the pixelated light source. The actuation and control of the change of position of the mirrors for selectively activating this elementary emitter to emit or not an elementary light beam is controlled by the control center.

In different embodiments, the matrix arrangement may comprise a scanning laser system wherein a laser light source emits a laser beam towards a scanning element which is configured to explore the surface of a wavelength converter with the laser beam. An image of this surface is captured by the projection optical element.

The exploration of the scanning element may be performed at a speed sufficiently high so that the human eye does not perceive any displacement in the projected image.

The synchronized control of the ignition of the laser source and the scanning movement of the beam makes it possible to generate a matrix of elementary emitters that can be activated selectively at the surface of the wavelength converter element. The scanning means may be a mobile micro-mirror for scanning the surface of the wavelength converter element by reflection of the laser beam. The micro-mirrors mentioned as scanning means are for example MEMS type, for “Micro-Electro-Mechanical Systems”. However, the invention is not limited to such a scanning means and can use other kinds of scanning means, such as a series of mirrors arranged on a rotating element, the rotation of the element causing a scanning of the transmission surface by the laser beam.

In another variant, the light source may be complex and include both at least one segment of light elements, such as light emitting diodes, and a surface portion of a monolithic light source.

FIG. 2 shows a first image of the photometry of a welcome light functionality which is to be projected by an automotive lighting device according to the invention.

This first image may be divided into pixels and each pixel may be characterized by its luminous intensity, in a scale from 0, which would correspond to black, to 255, which would correspond to white.

This image is the first image of a dynamic animation, which comprises a plurality of frames.

FIG. 3 shows a simplified version of such a pixel matrix, called image pattern 1. Each pixel 11 of this image pattern 1 is characterized by a number according to the aforementioned scale.

For the sake of clarity, not to use hundreds of rows and columns, this example does not correspond to the light pattern of FIG. 1, but the correspondence with the real-life images is direct.

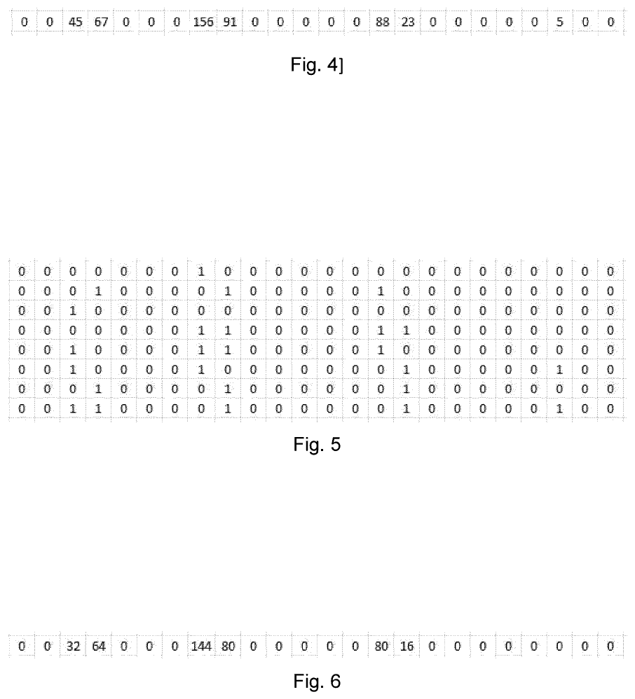

FIG. 4 shows how this matrix is flattened into one single row by placing the values of a row after the previous row. Then, the matrix of 4×6 values is transformed into a single unidimensional array of 1×24.

In this row, there are some pixels which have an intensity value equal to zero, and other pixels which have an intensity value different from zero.

FIG. 5 shows a next step in the method. The values of the unidimensional array are expressed with 8 bits (each column represents the 8-bit equivalence of the value of each pixel). Only the first four bits of the value are used as the relevant portion of this value.

FIG. 6 shows the relevant values converted again to the decimal system. There has been a loss of information, but there has also been a saving in the data size, since the relevant values are 4-bit values, instead of the 8-bit size of the original values.

Once this form is achieved, the compressed data may be elaborated according to different algorithms.

In a first algorithm, the following steps are followed:

counting the pixels with value equal to zero until arriving at a pixel with a value different to zero, storing the number of pixels with zero-value as the first position of a first vector (in this case, this first position would be “2”, since only two zeros are present until arriving at the first non-zero value, which is the third value of the unidimensional array)

store the relevant value of these pixels in a second vector (in this case, these relevant values would be “(32, 64)”

counting the pixels with value equal to zero until arriving at the next pixel with a value different to zero, storing the number of pixels as the subsequent position of the first vector (in this case, “3”)

repeating the steps of storing the relevant values and the number of zeros until reaching the end of the row.

According to this method, and, for the array of FIG. 6, the compressed data comprises a plurality of vectors:

a first vector with “zero countings” (2, 3, 5, 8)

a second vector with the first data segment (32, 64)

a third vector with the second data segment (144, 80)

a fourth vector with the third data segment (80, 16)

Although this example is not very close to reality, it means to see the power of this method: instead of storing 24 values of 8-bit (192 bits), the method stores 10 values of 4-bit (40 bits).

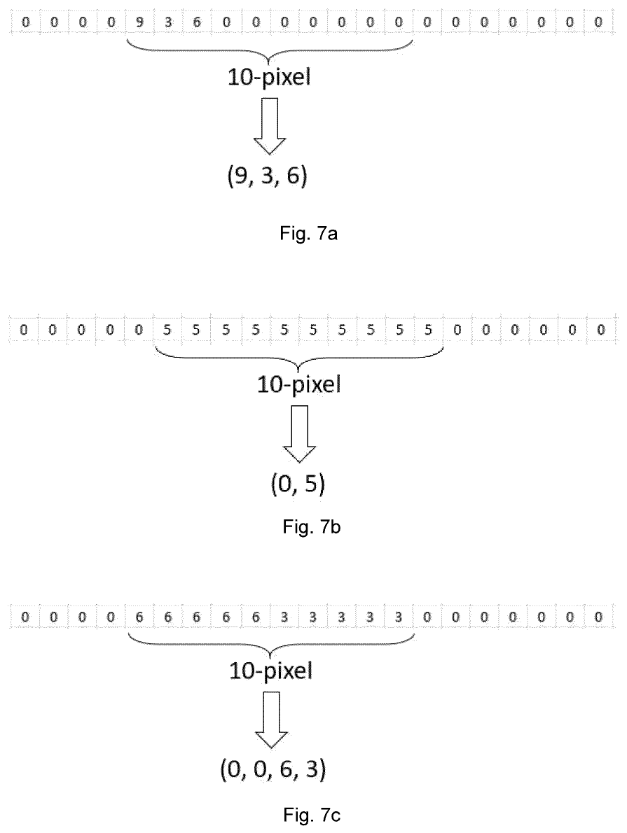

FIGS. 7a to 7c show different examples of how to create the compressed data using a particular key.

For these examples, the data segments will be considered to start in the first non-zero value and have a length of 10 pixels.

In FIG. 7a, the first four zeros will be stored in the “zero countings vector” (the same as in the case of FIG. 6) and the first data segment comprises the values 9-3-6-0-0-0-0-0-0-0. Since there are a lot of zeros, only the non-zero values are stored (9, 3, 6). Since the system knows that the data segments are 10-pixel long, the system knows that the rest of the values are zero.

In FIG. 7b, the first five zeros will be stored in the “zero countings vector” and the first data segment comprises the values 5-5-5-5-5-5-5-5-5-5. Since all the pixels have the same value, the key data will comprise a key (a first zero) and then the value that is repeated: (0, 5). Since a data segment cannot start with a zero (because the first value of a data segment is the first non-zero value found after the zeros chain), the presence of a zero as the first value of the key data indicates a key.

In FIG. 7c, the first four zeros will be stored in the “zero countings vector” and the first data segment comprises the values 6-6-6-6-6-3-3-3-3-3. These data can be divided into two halves: 6-6-6-6-6 and 3-3-3-3-3. Each portion is constant, so a “double-zero” key is used to express that the segment includes two halves, each one having a constant value: (0, 0, 6, 3).

In some cases, which applies to the cases of FIGS. 7b and 7c, the condition of the values being “the same” is also satisfied when they are all comprised within a range of two standard deviations. The mean value is chosen as the representative value. For example, a data segment of (5, 5, 4, 5, 2, 2, 1, 2) would also be stored as (0, 0, 5, 2). Then, in the decompressed step, the decompressed data segment would be (5, 5, 5, 5, 2, 2, 2, 2): there would be some loss of information.

What is claimed is:

1. A method for managing an image in an automotive lighting device, comprising:
providing a first image pattern comprising a plurality of pixels, wherein each pixel is characterized by a value related to the luminous intensity of the pixel, wherein the value of a plurality of pixels is zero;
selecting a relevant portion of the value of each pixel, thus obtaining relevant values; and
preparing compressed data related to the relevant values, together with data related to the position of the pixel with a value equal to zero.

2. The method according to claim 1, wherein the light pixels of the image pattern are greyscale pixels, and more particularly, the luminous intensity of each pixel is characterized by a number according to a scale from 0 to 255, so that each value related to the luminous intensity may be expressed with 8 bits.

3. The method according to claim 2, wherein the relevant portion of each value are the first 4 bits of the corresponding value.

4. The method according to claim 1, wherein the relevant values are arranged in a unidimensional array, and the compressed data includes
a first number of consecutive zeros from the start of the unidimensional array until arriving at a data segment
key data referred to a data segment with non-zero values; and
successively the number of consecutives zeros until the next data segment and the key data referred to the next data segment.

5. The method according to claim 4, wherein all the data segments include the same number of pixels.

6. The method according to claim 1, wherein the key data is obtained by applying a key on the values of the data segment.

7. The method according to claim 6, wherein a first value of the key involves that all the values of the segment are the same.

8. The method according to claim 7, wherein a second value of the key involves that a first portion of the segment have pixels which have the same first value and a second portion of the segments have pixels which have the same second value.

9. The method according to claim 8, further comprising:
sending the compressed data to a light module of the automotive lighting device; and
decompressing the compressed data by the light module.

10. An automotive lighting device, comprising:
a light module including a plurality of light sources; and
a control unit configured to:
provide a first image pattern comprising a plurality of pixels, wherein each pixel is characterized by a value related to the luminous intensity of the pixel, wherein the value of a plurality of pixels is zero;
select a relevant portion of the value of each pixel, thus obtaining relevant values; and
prepare compressed data related to the relevant values, together with data related to the position of the pixel with a value equal to zero.

11. An automotive lighting device according to claim 10, wherein the light module further comprises a processor unit, the processor unit being configured to decompress the compressed data.

12. An automotive lighting device according to claim 10, wherein the light sources are solid-state light sources, such as LEDs.
